(19) United States
(12) Patent Application Publication
(10) Pub. No.: US 2010/0155103 A1
(43) Pub. Date: Jun. 24, 2010

(54) ELECTRICALLY CONDUCTIVE INK

(75) Inventors: Yoichi Kamikoriyama, Ageo-shi (JP); Kenji Suzuoka, Ageo-shi (JP)

Correspondence Address: YOUNG & THOMPSON, 209 Madison Street, Suite 500, Alexandria, VA, 22314, US

(73) Assignee: MITSUI MINING & SMELTING CO., LTD., TOKYO (JP)

(21) Appl. No.: 12/161,094

(22) PCT Filed: Dec. 20, 2006
(86) PCT No.: PCT/JP2006/325417

§ 371 Date: Jul. 16, 2008

(30) Foreign Application Priority Data
Mar. 20, 2006 (JP) 2006-077097

(51) Int. Cl. H05K 3/00; H01B 1/22; H01B 5/00

(52) U.S. Cl. 174/126.1; 252/514; 427/98.4

(57) ABSTRACT

The invention relates to an electrically conductive ink comprising fine metal particles, an inorganic binder, and a solvent. The inorganic binder comprises a coupling agent containing Ti or Al or a chelate containing Ti or Al. It is preferred that the inorganic binder is present in an amount of 1 to 50 parts by weight per 100 parts by weight of the fine metal particles in the conductive ink. An electrical conductor thin film is produced by the process of printing the conductive ink on a substrate to form a printed pattern by additive processing and firing the printed pattern at 100° C. to 950° C.

### TECHNICAL FIELD

This invention relates to electrically conductive ink containing fine metal particles.

### BACKGROUND ART

Methods known for the formation of an electroconductive circuit pattern on various substrates include methods making use of photolithography and etching and a screen printing method (see Patent Document 1 and Patent Document 2). In particular, direct-write screen printing using an electrically conductive paste or ink containing metal particles has widely spread because it has a reduced number of steps and achieves production cost saving as compared with the patterning technique involving etching the copper foil of a copper clad laminate.

Screen printing, however, encounters difficulty in making a fine circuit pattern. Then, inkjet printing using electrically conductive ink has recently been proposed as another direct-write patterning technique (see Patent Document 3). The problem associated with the inkjet printing technique is that the printed circuit pattern has insufficient adhesion to a variety of substrates. This problem arises from the fact that a printed pattern relies on the organic resin used in the ink for adhesion to a substrate.

To provide a manganese intermediate layer has been proposed to improve the adhesion of a printed pattern as reported in Non-Patent Document 1. The method cannot be regarded as economical because of the involvement of the step for forming the Mn intermediate layer.

It has been proposed to add a sulfur compound such as a thiol or a thiourea to an electrically conductive ink as a dispersing aid to improve dispersibility of metal particles (see Patent Document 4 and Patent Document 5). However, the sulfur content reacts with the metal to form a metal sulfide, which, being an insulator, increases the electrical resistance of the circuit. Furthermore, an electrically conductive ink containing sulfur is unsuited for application to electronic materials demanding high reliability because the sulfur content is liable to migration.

In order to secure electrical conductivity, it is necessary to remove a dispersing agent and a solvent from the surface of metal particles by firing thereby to bring the particles into direct contact with each other as described in Non-Patent Document 2. However, firing proceeds excessively to completely fuse the particles together because the fine metal particles unprotected by a protective agent exhibit extremely high activity on their surface at high temperature. The fusion of the particles affects dimensional stability of the resulting circuit. To solve this problem, Patent Document 6 proposes using a paste comprising a dispersion of fine metal particles in an organic solvent and a silane coupling agent and firing the paste applied on a glass substrate at low temperature of 250° C. to 300° C. This method has the following disadvantages. Because the method uses a silane coupling agent having a mercapto group, the sulfur content of the mercapto group reacts with the metal to form an insulating metal sulfide, resulting in increased electrical resistance of the circuit. The circuit is unable to maintain the form of the electrodes in high temperature on account of the reactivity between Si and Ag, posing the problem of low resistance to heat and shrinkage. Firing produces an oxide of Si from the silane coupling agent. Having a low glass transition point, the Si oxide melts easily by the heat of firing, which makes it difficult to effectively prevent the fine metal particles from fusing to each other. The method relies on subtractive processing using photolithography to form an electrical conductor thin film. This means an increased number of steps involved and an increased amount of materials used, making the method uneconomical. Moreover, the method imposes a great burden on the environment.

Patent Document 1 JP 9-246688A

Patent Document 2 JP 8-18190A

Patent Document 3 JP 2002-324966A

Patent Document 4 JP 2005-60816A

Patent Document 5 JP 2004-311265A

Patent Document 6 JP 2004-179125A

Non-Patent Document 1 Tadaaki Oda, “Advance of Maskless Fine Wiring Formation Technique”, Proc. Nagano Jisso Forum 2005, pp. 9-30 (June, 2005).

Non-Patent Document 2 Tadaaki Oda, Kogyo Zairyo, “Film Formation by Existing Printing Techniques using Metal Nanoparticle Ink and Paste”, vol. 53, No. 5, pp. 54-57 (May, 2005)

### DISCLOSURE OF THE INVENTION

The present invention provides an electrically conductive ink containing fine metal particles, an inorganic binder, and a solvent. The ink is characterized in that the inorganic binder comprises a coupling agent containing Ti or Al or a chelate containing Ti or Al.

The invention also provides a process of making an electroconductor thin film including printing the above described electrically conductive ink on a substrate to form a printed pattern by additive processing and firing the printed pattern at 100° C. to 950° C.

The invention also provides an electroconductor thin film formed by firing the above described electrically conductive ink, in which film the individual fine metal particles are nearly spherical and in electrical contact with each other.

### BRIEF DESCRIPTION OF THE DRAWINGS

FIG. 1 is an SEM micrograph of each electrical conductor thin film formed of the ink prepared in Example 1.

FIG. 2 is an SEM micrograph of each electrical conductor thin film fanned of the ink prepared in Example 2.

FIG. 3 is an SEM micrograph of each electrical conductor thin film formed of the ink prepared in Example 3.

FIG. 4 is an SEM micrograph of each electrical conductor thin film formed of the ink prepared in Comparative Example 1.

FIG. 5 is an SEM micrograph of each electrical conductor thin film formed of the ink prepared in Comparative Example 2.

### BEST MODE FOR CARRYING OUT THE INVENTION

The electrically conductive ink of the present invention contains fine metal particles, an inorganic binder, and a solvent. The conductive ink can be applied to a substrate to form a coating film in a prescribed pattern. Firing the coating film provides an electrical conductor thin film having a pattern corresponding to the prescribed pattern. The resulting conductor thin film has excellent adhesion to the substrate as well as excellent resistance to heat and shrinkage. Formation of an electrical conductor thin film with such excellent characteristics can be accomplished by the conductive ink of the invention which contains the components described.

The electrically conductive ink of the invention provides an electrical conductor thin film with improved various characteristics by using an inorganic binder containing Ti or Al. The term “inorganic binder” as used herein denotes a Ti- or Al-containing compound capable of forming, on the surface of the fine metal particles on firing, an inorganic compound with the metal, such as an oxide of the metal. Accordingly, the inorganic binder that can be used in the invention may have an organic group containing a carbon atom before being fired. The inorganic compound such as a Ti oxide or an Al oxide formed on the surface of the fine metal particles on firing the inorganic binder functions to prevent excessive fusion between the fine metal particles. It is preferred that the inorganic binder before firing has a reactive group capable of firmly bonding the surface of the fine metal particles to the surface of a substrate.

The proportion of the inorganic binder in the conductive ink is influential on various characteristics of the conductor thin film obtained by firing. Seeing that the function of the inorganic binder is to form a firm bond between the fine metal particles and a substrate and to prevent excessive fusion between the fine metal particles, the proportion of the inorganic binder is preferably decided in relation to the amount of the fine metal particles. From this viewpoint, the amount of the inorganic binder in the conductive ink is preferably 1 to 50 parts, more preferably 3 to 30 parts, even more preferably 5 to 20 parts, per 100 parts by weight of the fine metal particles. If the amount of the inorganic binder is too small with respect to the metal particles, it is not easy to prevent excessive fusion between the metal particles. If the amount is too large, a considerable amount of a decomposition product will be produced on firing the ink film, which tends to induce defects such as cracks in the resulting conductor film.

While the compounding ratio of the inorganic binder to the fine metal particles is as stated above, the proportion of the inorganic binder in the whole ink composition is preferably 0.1% to 29% by weight, more preferably 1% to 13% by weight.

The inorganic binder that can be used in the invention comprises a Ti- or Al-containing coupling agent or chelate. The Ti- or Al-containing coupling agent or chelate is not particularly limited as long as it is compatible with a solvent. The Ti- or Al-containing coupling agent and chelate can be used either alone or in any combination thereof.

Examples of the Ti-containing coupling agent or chelate include tetraisopropyl titanate, tetra-n-butyl titanate, butyl titanate dimer, tetra(2-ethylhexyl)titanate, tetramethyl titanate, titanium acetyl acetonate, titanium tetraacetylacetonate, titanium ethylacetoacetate, titanium octanediolate, titanium lactate, titanium triethanolaminate, and polyhydroxytitanium stearate. Commercially available products such as PLENACT® KR-ET from Ajinomoto Fine-Techno Co., Inc. are also useful.

Examples of the Al-containing coupling agent or chelate include aluminum isopropylate, mono-sec-butoxyaluminum diisopropylate, aluminum sec-butylate, aluminum ethylate, ethylacetoacetatoaluminum diisopropylate, aluminum tris(ethylacetoacetate), alkylacetoacetatealuminum diisopropylates, aluminum monoacetylacetonate bis(ethylacetoacetate), aluminum tris(acetylacetonate), aluminum monoisopropoxymonooleoxyethylacetoacetate, cyclic aluminum oxide isopropylate, aluminum isopropoxyalkylacetoacetate 2-ethylhexyl acid phosphate, cyclic aluminum oxide octylate, and cyclic aluminum oxide stearate. Alumichelate P-1 (trade name), an aluminum chelate available from Kawaken Fine Chemical Co., Ltd., is also useful.

The above described inorganic binder may be used in combination with an Si- or Zr-containing coupling agent or chelate. A combined use of an Si- or Zr-containing coupling agent or chelate ensures the prevention of fusion between the fine metal particles during firing. It is preferred that these coupling agents or chelates to be used in combination are free from sulfur. Examples of the Si-containing coupling agent or chelate include vinyltrichlorosilane, vinyltrimethoxysilane, vinyltriethoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, p-styryltri-methoxysilane, 3-methacryloxypropylmethyldimethoxysilane, 3-methacryloxypropyl-trimethoxysilane, 3-methacryloxypropylmethyldiethoxysilane, 3-methacryloxypropyl-triethoxysilane, 3-acryloxypropyltrimethoxysilane, N-2-(aminoethyl)-3-aminopropyl-methyldimethoxysilane, N-2-(aminoethyl)-3-aminopropyltriethoxysilane, 3-aminopropyltrimethoxysilane, 3-aminotriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, 3-ureidopropyltriethoxy-silane, 3-chloropropyltrimethoxysilane, 3-isocyanatopropyltriethoxysilane, tetramethoxysilane, tetraethoxysilane, methyltrimethoxysilane, methyltriethoxysilane, dimethyltriethoxysilane, phenyltriethoxysilane, hexamethyldisilazane, hexyltrimethoxysilane, and decyltrimethoxysilane.

Examples of Zr-containing coupling agent or chelate include zirconium n-propylate, zirconium n-butylate, zirconium tetraacetylacetonate, zirconium monoacetylacetonate, zirconium bisacetylacetonate, zirconium monoethylacetoacetate, zirconium acetylacetonate bisethylacetoacetate, zirconium acetate, and zirconium monostearate.

The fine metal particles in the conductive ink of the invention preferably has a particle size of 1 to 300 nm, more preferably 5 to 100 nm. When, in particular, the ink of the invention is applied to inkjet printing as will be described later, the metal particle size is preferably 5 to 100 nm, more preferably 5 to 80 nm, to prevent nozzle clogging. Metal particles having particle sizes in the recited range are generally called nanoparticles. Metal nanoparticles are characterized by having atoms located on the particle surface in a very large proportion and exhibit different properties from bulk metal. For example, metal nanoparticles fuse together at temperatures below the melting point of the bulk metal, while depending on the particle size. In the present invention, this melting point depression phenomenon is taken advantage of to accomplish firing of an ink coating film at relatively low temperatures. To fire in low temperature is also advantageous in suppressing fusion bonding of the fine metal particles to each other. Nevertheless, because of the existence of the inorganic binder in the ink, fusion of fine metal particles hardly occurs even if the ink is fired at high temperature. The particle size of the fine metal particles is measured under a scanning electron microscope (FE-SEM from FEI Company) or a transmission electron microscope (H9000-NAR from Hitachi, Ltd.) or with a submicron particle analyzer (N5 from Beckman Coulter Inc.).

The fine metal particles to be used are not limited in kind. For example, metal elemental substances, alloys, and mixtures of two or more thereof can be used. Examples of the metal include, but are not limited to, gold, silver, platinum, palladium, copper, nickel, cobalt, iron, molybdenum, tungsten, indium, and tin. Silver and silver alloys (e.g., silver-platinum alloy and silver-palladium alloy) are preferred for their low specific resistance. The fine metal particles are in a uniformly dispersed state in the ink.

While the proportion of the fine metal particles in the ink is decided according to the above-recited inorganic binder to metal particle ratio, it is preferably 10% to 79% by weight, more preferably 20% to 72% by weight.

The fine metal particles can be prepared by known processes. For example, a solid or liquid metal compound (such as an oxide, a hydroxide or a salt of gold, silver, palladium, etc.) is suspended in a polyol, and the suspension is heated at 85° C. or higher to reduce the compound to the corresponding metal particles. Examples of the polyol include liquid aliphatic glycols and polyethers of the glycols. The process of preparing fine metal particles as described is disclosed, e.g., in JP 4-24402B.

Fine particles of a silver alloy can be prepared by, for example, adding sodium borohydride to a palladium compound aqueous solution to prepare a palladium colloid, adding L-ascorbic acid or an L-ascorbic acid salt to the colloid, and further adding a silver compound aqueous solution to reduce silver. This process is taught, e.g., in Japanese Patent 2550156.

Another process of preparing fine particles of a silver alloy comprises mixing and dissolving silver and at least one member selected from the group consisting of palladium, gold, and platinum to prepare an alloy base material, dissolving the alloy base material in nitric acid to prepare a solution, adjusting the pH of the solution by the addition of an aqueous ammonia solution and adding hydrazine and/or a hydrazine compound as a reducing agent to reduce the metal ions in the solution. This process is described, e.g., in Japanese Patent 2550586.

A process of making fine metal particles in an oil phase is disclosed in JP 57-192206A, in which silver oxide powder is brought into contact with a heating medium oil in a temperature range of from 50° C. to 300° C. under reduced pressure. Examples of useful heating medium oil include mineral oils, animal or vegetable oils, silicone oils, and fluorine oils. Production of fine silver particles by heating silver soap (CₙH₂ₙ₊₁COOAg; n=1 to 9, 11, 13, 15 or 17) in various solvents at 50° C. to 150° C. is reported in Journal of the Chemical Society of Japan, (6), pp. 690-696, 1979.

The solvent that can be used in the ink of the invention preferably has a boiling point of 80° C. or higher, more preferably 150° C. or higher. The term “boiling point” as used herein means a boiling point under atmospheric pressure (1 atm.). Using a solvent whose boiling point is not lower than 80° C. prevents the ink from drying too rapidly. This is advantageous to prevent ink film defects thereby to obtain an electrical conductor film with desired characteristics. Although there is no particular upper limit of the boiling point of the solvent, a preferred boiling point is preferably 350° C. or lower, more preferably 300° C. or lower, in view of the drying speed of ink film.

The amount of the solvent is preferably 14% to 89.9% by weight, more preferably 22% to 79% by weight, based on the total ink composition.

The solvent may be either aqueous or nonaqueous. Useful solvents include water, polyhydric alcohols, polyhydric alcohol alkyl ethers, polyhydric alcohol aryl ethers, esters, nitrogen-containing heterocyclic compounds, amides, amines, long chain alkanes, cyclic alkanes, aromatic hydrocarbons, and monohydric alcohols. These solvents may be used either individually or as a combination of two or more thereof.

Examples of the polyhydric alcohols are ethylene glycol, propylene glycol, 1,3-propanediol, 1,4-butanediol, 1,5-pentanediol, diethylene glycol, dipropylene glycol, and triethylene glycol.

Examples of the polyhydric alcohol alkyl ethers include ethylene glycol monomethyl ether, ethylene glycol monoethyl ether, ethylene glycol monobutyl ether, diethylene glycol monomethyl ether, diethylene glycol monoethyl ether, diethylene glycol monobutyl ether, triethylene glycol monomethyl ether, triethylene glycol monoethyl ether, and propylene glycol monobutyl ether.

The polyhydric alcohol aryl ethers are exemplified by ethylene glycol monophenyl ether. Examples of the esters are ethyl cellosolve acetate, butyl cellosolve acetate, and γ-butyrolactone. Examples of the nitrogen-containing heterocyclic compounds are N-methylpyrrolidone and 1,3-dimethyl-2-imidazolidinone. Examples of the amides are formamide, N-methylformamide, and N,N-dimethylformamide. Examples of the amines include monoethanolamine, diethanolamine, triethanolamine, tripropylamine, and tributylamine.

Examples of the long chain alkanes include heptane, octane, nonane, decane, undecane, dodecane, tridecane, and tetradecane. The cyclic alkanes are exemplified by cyclohexane and decaline. Examples of the aromatic hydrocarbons are benzene, toluene, xylene, dodecylbenzene, and trimethylbenzene. Examples of the monohydric alcohols include propanol, butanol, pentanol, hexanol, heptanol, octanol, decanol, cyclohexanol, terpineol, benzyl alcohol, 2-propanol, sec-butanol, t-butanol, 2-pentanol, 3-pentanol, 2-ethyl-1-butanol, 2-heptanol, 3-heptanol, 2-octanol, 3-octanol, 4-octanol, 2-ethylhexanol, and nonanol.

The electrically conductive ink of the invention can contain other components to improve various ink performance properties in addition to the aforementioned components. The other components include a viscosity modifier, a surface tension modifier, a dispersing aid, and an anti-foaming agent. Even without such additive components, however, an electrical conductor thin film can be obtained from the ink composition consisting of the above-described components.

The electrically conductive ink of the invention may have a viscosity controlled in a broad range. Specifically, the conductive ink preferably has a viscosity of 100 mPa·s or less, more preferably 50 mPa·s or less, at 20° C. The viscosity of the ink can be adjusted by the compounding ratio of the above described components. The viscosity is measured with an oscillation viscometer (VM-100A from Yamaichi Electronics Co., Ltd.) or a rheometer (RS-1 from HAAKE).

In the cases where the electrically conductive ink of the invention is applied by inkjet printing as described later, the viscosity of the ink is preferably 50 mPa·s or less, more preferably 30 mPa·s or less, at 20° C.

The electrically conductive ink of the invention is prepared by, for example, as follows. To start with, fine metal particles are prepared in accordance with any of the aforementioned processes. The process in which fine metal particles are formed in a liquid phase having a boiling point of 80° C. or higher is preferred because the liquid phase can serve as such as a solvent. The resulting fine metal particles are dispersed in a solvent into slurry. The metal particles concentration in the slurry is preferably 10% to 80%, more preferably 20% to 75%, by weight depending on a desired ink viscosity. To the slurry is added an inorganic binder preferably in an amount of 1 to 50 parts, more preferably 3 to 30 parts, by weight per 100 parts by weight of the metal particles, and the mixture is stirred to provide a desired ink.

The thus obtained ink has the fine metal particles completely dispersed in the solvent. In the case where the ink is applied by inkjet printing as described later, the ink behaves like water at ambient temperature (20° C.) under normal pressure (1 atm.), which depends on the viscosity.

The electrically conductive ink of the invention is suitable as a circuit-forming material used in electronic devices having a laminate structure and single-layer or multilayer printed wiring boards. Specifically, the ink of the invention is printed on a substrate of various materials such as glass, ceramics, metals, and plastics by a known printing technique in a prescribed pattern, and the printed pattern is fired in the air. The firing may be carried out in an inert atmosphere or in vacuo. A desired electrical conductor thin film is thus formed.

Since the above-described process of electrical conductor film formation is a fully additive processing method in which a requisite amount of ink is applied to only where it is needed, the process achieves great reduction in material cost and processing cost compared with the subtractive processing described in Patent Document 1 and Patent Document 6 supra.

Printing methods adapted in forming an ink coating film by additive processing include inkjet printing, screen printing, gravure printing, offset printing, and dispenser printing. Preferred of them is inkjet printing because of capability of forming a fine pitch circuit pattern, capable of direct-writing on a substrate, freedom of computer-aided pattern designing, and the like. Inkjet printing technology is roughly divided into a piezoelectric system and a thermal system, to either of which the ink of the invention is applicable.

The ink of the invention provides an electrical conductor thin film with satisfactory characteristics even if the firing conditions are varied widely. For instance, the firing temperature ranges preferably from 100° C. to 950° C., more preferably from 130° C. to 800° C., even more preferably 150° C. to 600° C. The firing time is selected from such a wide range of from several tens of minutes to about 200 hours. When a conventional ink is fired at high temperatures or for a long period of time, the fine metal particles undergo fusion to each other only to provide an electrical conductor thin film with poor dimensional stability. Contrary to this, the ink of the invention provides an electrical conductor thin film with high dimensional stability even when fired at a high temperature or for a long time. Even when fired at a high temperature or for a long time, the ink of the invention shows no excessive increase in specific resistance and maintains substantially the same surface smoothness as before firing, providing a mirror surface.

The inventors have confirmed as a result of electron microscopic observation of a cross-section of an electrical conductor thin film obtained after firing that the fine metal particles unexpectedly have substantially the same spherical shape as before the firing. The reason is assumed to be that the inorganic binder in the ink is oxidized by firing to moderately cover the surface of the fine metal particles and, as a result, prevents the fine metal particles from fusing to each other. Therefore, the conductor thin film formed by using the ink of the invention exhibits high resistance to heat and shrinkage (high dimensional stability). In order for an electronic device to have increased reliability, it is important for the electronic device to have an electrical conductor thin film with high heat resistance and shrinkage resistance.

The inventors have also confirmed that the conductor thin film formed by using the conductive ink of the invention has high adhesion to a substrate. The reason is assumed to be that the inorganic binder in the ink mediates between the fine metal particles and the substrate, forming a firm bond therebetween.

As described, the conductor thin film formed by using the conductive ink of the invention has the noteworthy characteristics of both (1) high heat resistance and shrinkage resistance and (2) high adhesion to a substrate. In the conductor thin film the fine metal particles maintain almost spherical shapes and keep electrical contact with each other. In contrast, a conventional electrically conductive ink, for example the ink of Comparative Example 1 hereinafter given, has a high specific resistance, and the fine metal particles of which fail to retain their original spherical shape as a result of fusion on firing, so that the resulting conductor film has insufficient heat resistance and shrinkage resistance.

### EXAMPLES

The present invention will now be illustrated in greater detail with reference to Examples, but it should be understood that the invention is not deemed to be limited thereto. Unless otherwise noted, all the percents and parts are by weight.

### Example 1

### (1) Preparation of Ink

Fine silver particles were prepared in an oil phase. The resulting silver particles had a particle size of 10 nm. The silver particles were dispersed in tetradecane to prepare a 73% slurry. The concentration of the silver particles was obtained from the ignition loss of the slurry after heating at 600° C. for 1 hour. To a 50 g portion of the slurry was added 3.65 g (equivalent to 10 parts per 100 parts of the silver particles) of Plenact KR ET from Ajinomoto Fine-Techno Co., Inc. as an inorganic binder. The mixture was stirred while defoaming in a defoaming mixer (from Thinky Corp.) to give an electrically conductive ink. The resulting ink had a silver particle concentration of 68%, an inorganic binder concentration of 7%, and a solvent concentration of 25% and a viscosity (at 20° C.) of 24 mPa·s.

### (2) Formation of Electrical Conductor Thin Film

The electrically conductive ink was applied to an alkali-free glass substrate (OA-10 from Nippon Electric Glass Co., Ltd.) with a spin coater (from MIKASA Co., Ltd.) at 1000 rpm for 10 seconds to form a film. The coating film was dried by heating at 100° C. for 10 minutes in the air and then fired in the air at 150° C., 200° C., 300° C., 400° C., 500° C. or 600° C. each for 1 hour to form an electrical conductor thin film. Separately, the dried coating film was fired in the air at 300° C. for 0.5 hours, 1 hour, 5 hours, 10 hours, 60 hours, or 170 hours to obtain an electrical conductor thin film.

### (3) Evaluation

The electrical conductor thin films thus formed were evaluated for heat resistance, shrinkage resistance, adhesion to substrate, and surface smoothness in accordance with the following methods. The results obtained are shown in Table 1 below.

### (3-1) Evaluation of Heat Resistance and Shrinkage Resistance

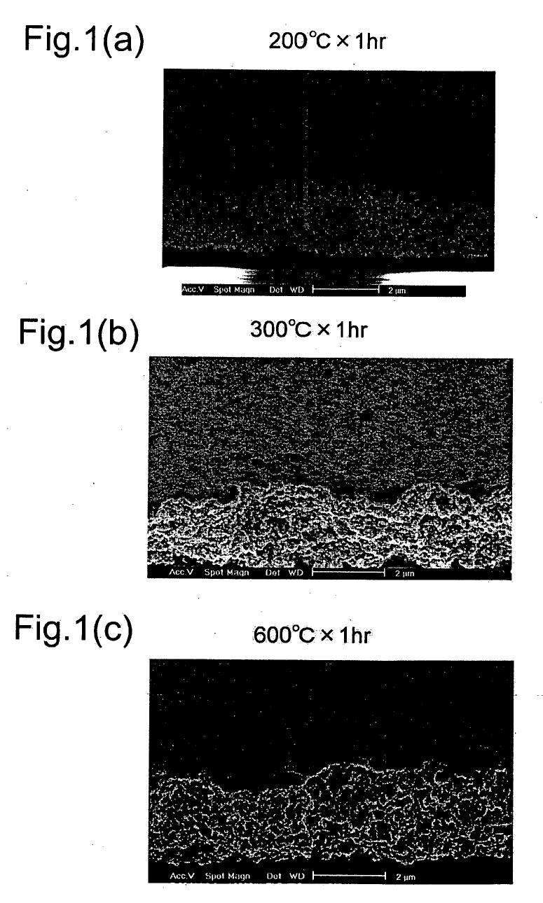

A cross-section of the electrical conductor thin film was observed under a scanning electron microscope (FE-SEM from FEI Company) to examine the shape of particles inside the film and to measure the film thickness. The specific resistance of the film was measured with a four-probe resistivity measuring device (Lorest GP from Mitsubishi Chemical Corp.). The SEM micrographs of the electrical conductor thin films obtained by the firing at 200° C.×1 hour, 300° C.×1 hour, and 600° C.×1 hour are shown in FIG. 1.

### (3-2) Evaluation of Adhesion to Substrate

The adhesion of the electrical conductor thin film to the glass substrate was evaluated by the cross-cut test specified in JIS K5600.

### (3-3) Evaluation of Surface Smoothness

The surface condition of the electrical conductor thin film was observed with the naked eye and rated good (totally mirror surface) or bad (foggy and uneven).

TABLE 1

| | | | | | | |
|---|---|---|---|---|---|---|
| Firing Temp. (° C.) | 150 | 200 | 300 | 400 | 500 | 600 |

| | |
|---|---|
| Firing Time (hr) | 1 |

Evaluation:

| Inside | nearly | nearly | nearly | nearly | nearly | nearly |
|---|---|---|---|---|---|---|
| Particle Shape | spherical | spherical | spherical | spherical | spherical | spherical |
| Film | 2 | 2 | 2 | 2 | 2 | 2 |
| Thickness (μm) | | | | | | |
| Specific | 3 × 10⁻⁵ | 1 × 10⁻⁵ | 5 × 10⁻⁶ | 5 × 10⁻⁶ | 4 × 10⁻⁶ | 3 × 10⁻⁶ |
| Resistance (Ω · cm) | | | | | | |
| Adhesion (class) | 0 | 0 | 0 | 0 | 0 | 0 |
| Surface Smoothness | good | good | good | good | good | good |
| Firing Temp. (° C.) | 300 | | | | | |
| Firing Time (hr) | 0.5 | 1 | 5 | 10 | 60 | 170 |

Evaluation:

| | | | | | | |
|---|---|---|---|---|---|---|
| Inside | nearly | nearly | nearly | nearly | nearly | nearly |
| Particle Shape | spherical | spherical | spherical | spherical | spherical | spherical |
| Film | 2 | 2 | 2 | 2 | 2 | 2 |
| Thickness (μm) | | | | | | |
| Specific | 6 × 10⁻⁶ | 5 × 10⁻⁶ | 5 × 10⁻⁶ | 5 × 10⁻⁶ | 4 × 10⁻⁶ | 4 × 10⁻⁶ |
| Resistance (Ω · cm) | | | | | | |
| Adhesion (class) | 0 | 0 | 0 | 0 | 0 | 0 |
| Surface Smoothness | good | good | good | good | good | good |

### Example 2

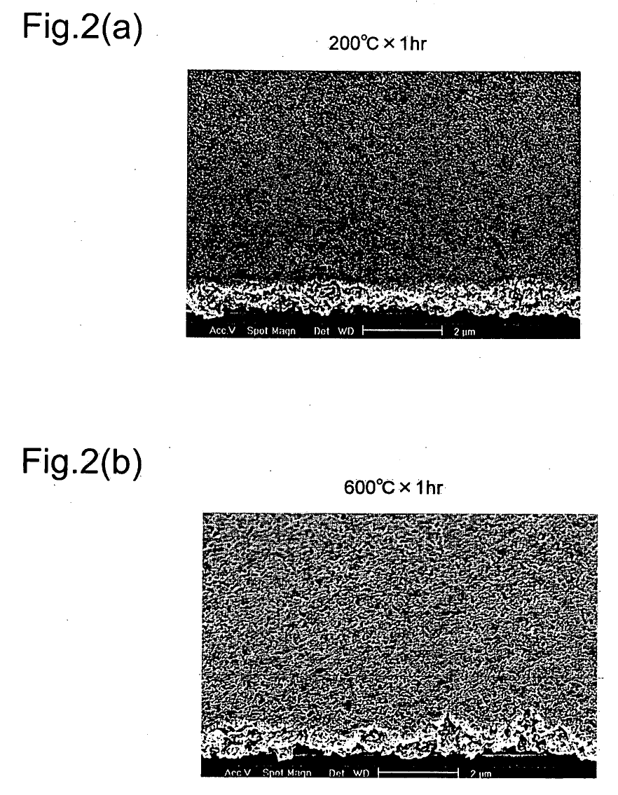

Fine silver particles prepared in the same manner as in Example 1 were dispersed in tetradecane to prepare a 60% slurry. To a 50 g portion of the slurry was added 2.10 g (equivalent to 7 parts per 100 parts of the silver particles) of Plenact KR ET from Ajinomoto Fine-Techno Co., Inc. as an inorganic binder. The mixture was processed in the same manner as in Example 1 to give an electrically conductive ink. The resulting ink had a silver particle concentration of 58%, an inorganic binder concentration of 4%, and a solvent concentration of 38% and a viscosity (at 20° C.) of 10 mPa·s. Electrical Conductor films were formed using the resulting ink in the same manner as in Example 1. The firing was conducted at 150° C., 200° C., 300° C., 400° C., 500° C. or 600° C. each for 1 hour. The resulting electrical conductor films were evaluated in the same manner as in Example 1. The results obtained are shown in Table 2 below. The SEM micrographs of the electrical conductor thin films obtained by the firing at 200° C.×1 hour and 600° C.×1 hour are shown in FIG. 2.

TABLE 2

| | | | | | | |
|---|---|---|---|---|---|---|
| Firing Temp. (° C.) | 150 | 200 | 300 | 400 | 500 | 600 |

| | |
|---|---|
| Firing Time (hr) | 1 |

Evaluation:

| | | | | | | |
|---|---|---|---|---|---|---|
| Inside | nearly | nearly | nearly | nearly | nearly | nearly |
| Particle Shape | spherical | spherical | spherical | spherical | spherical | spherical |
| Film | 0.5 | 0.5 | 0.5 | 0.5 | 0.5 | 0.5 |
| Thickness (μm) | | | | | | |
| Specific | 5 × 10⁻⁵ | 3 × 10⁻⁵ | 4 × 10⁻⁶ | 4 × 10⁻⁶ | 4 × 10⁻⁶ | 3 × 10⁻⁶ |
| Resistance (Ω · cm) | | | | | | |
| Adhesion (class) | 0 | 0 | 0 | 0 | 0 | 0 |
| Surface Smoothness | good | good | good | good | good | good |

### Example 3

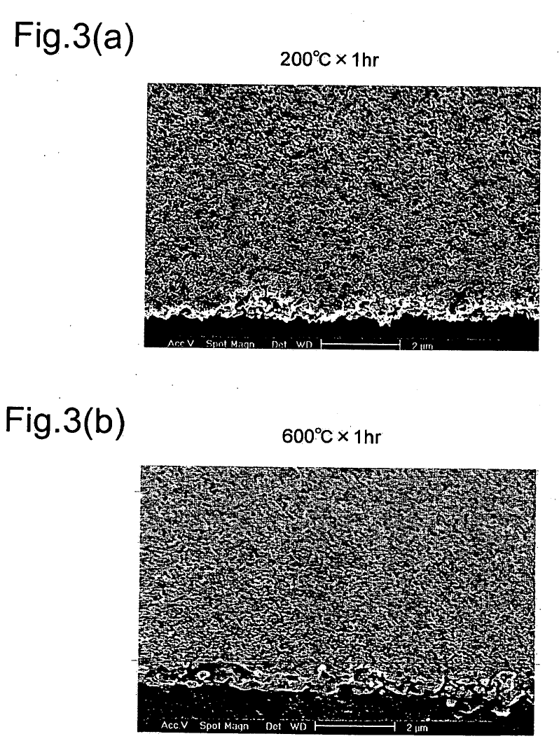

Fine silver particles were prepared in an oil phase. The particle size of the silver particles was 10 nm. The resulting silver particles were dispersed in decane to prepare a 40% slurry. To a 50 g portion of the slurry was added 2.0 g (equivalent to 10 parts per 100 parts of the silver particles) of Alumichelate P-1 from Kawaken Fine Chemical Co., Ltd. as an inorganic binder. The mixture was processed in the same manner as in Example 1 to give an electrically conductive ink. The resulting ink had a silver particle concentration of 38%, an inorganic binder concentration of 4%, and a solvent concentration of 58% and a viscosity (at 20° C.) of 3 mPa·s. Electrical Conductor thin films were formed using the resulting ink in the same manner as in Example 1. The firing was conducted at 150° C., 200° C., 300° C., 400° C., 500° C. or 600° C. each for 1 hour. The resulting electrical conductor thin films were evaluated in the same manner as in Example 1. The results obtained are shown in Table 3 below. The SEM micrographs of the electrical conductor films obtained by the firing at 200° C.×1 hour and 600° C.×1 hour are shown in FIG. 3.

TABLE 3

| | | | | | | |
|---|---|---|---|---|---|---|
| Firing Temp. (° C.) | 150 | 200 | 300 | 400 | 500 | 600 |

| | |
|---|---|
| Firing Time (hr) | 1 |

Evaluation:

| | | | | | | |
|---|---|---|---|---|---|---|
| Inside | nearly | nearly | nearly | nearly | nearly | nearly |
| Particle Shape | spherical | spherical | spherical | spherical | spherical | spherical |
| Film | 0.4 | 0.4 | 0.4 | 0.4 | 0.4 | 0.4 |
| Thickness (μm) | | | | | | |
| Specific | 7 × 10⁻⁵ | 5 × 10⁻⁵ | 6 × 10⁻⁶ | 6 × 10⁻⁶ | 6 × 10⁻⁶ | 5 × 10⁻⁶ |
| Resistance (Ω · cm) | | | | | | |
| Adhesion (class) | 0 | 0 | 0 | 0 | 0 | 0 |
| Surface Smoothness | good | good | good | good | good | good |

### Comparative Example 1

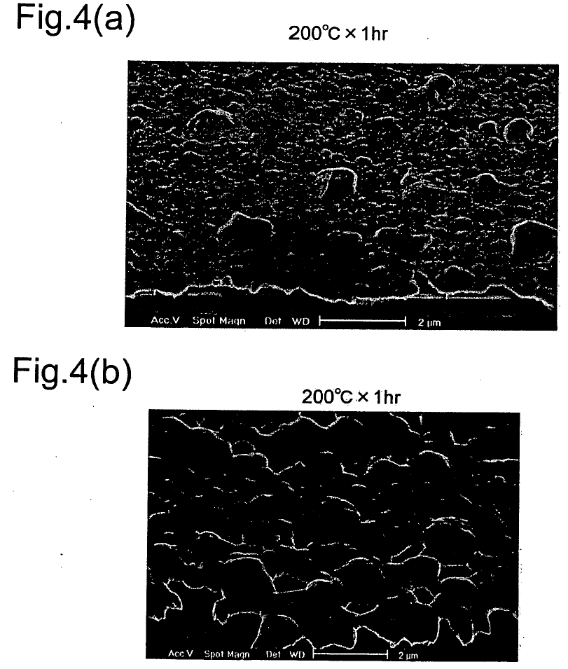

Fine silver particles were prepared in an oil phase. The particle size of the silver particles was 10 nm The resulting silver particles were dispersed in tetradecane to prepare a 60% slurry. To a 50 g portion of the slurry was added 3.0 g (equivalent to 10 parts per 100 parts of the silver particles) of γ-mercaptopropylmethyldimethoxysilane (KBM-802 from Shin-Etsu Chemical Co., Ltd.). The mixture was processed in the same manner as in Example 1 to give an electrically conductive ink. The resulting ink had a silver particle concentration of 56.5%, a γ-mercaptopropylmethyldimethoxysilane concentration of 5.7%, and a solvent concentration of 37.8% and a viscosity (at 20° C.) of 15 mPa·s. Electrical Conductor thin films were formed using the resulting ink in the same manner as in Example 1. The firing was conducted at 200° C., 300° C., 400° C., 500° C. or 600° C. each for 1 hour. The resulting electrical conductor thin films were evaluated in the same manner as in Example 1. The results obtained are shown in Table 4 below. The SEM micrographs of the electrical conductor thin films obtained by the firing at 300° C.×1 hour and 600° C.×1 hour are shown in FIG. 4.

TABLE 4

| | | | | | |
|---|---|---|---|---|---|
| Firing Temp. (° C.) | 200 | 300 | 400 | 500 | 600 |

| | |
|---|---|
| Firing Time (hr) | 1 |

Evaluation:

| | | | | | |
|---|---|---|---|---|---|
| Inside | nearly | nearly | nearly | filmy | filmy |
| Particle Shape | spherical | spherical | spherical | | |
| Film | 0.5 | 0.5 | 0.3 | unmeasurable | unmeasurable |
| Thickness (μm) | | | | | |
| Specific | 2 × 10⁻³ | 9 × 10⁻⁵ | 6 × 10⁻⁴ | — | — |
| Resistance (Ω · cm) | | | | | |
| Adhesion (class) | 2 | 0 | 2 | 5 | 5 |
| Surface Smoothness | bad | bad | bad | bad | bad |

### Comparative Example 2

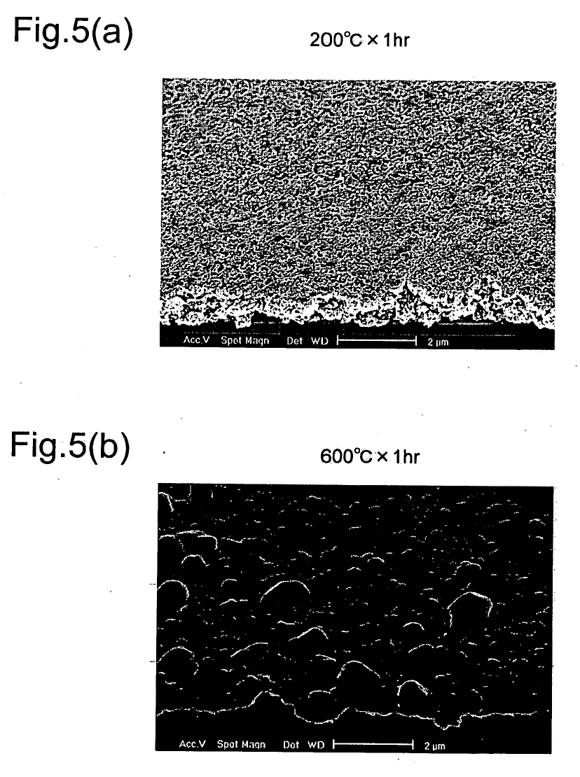

An electrically conductive ink was prepared in the same manner as in Example 1, except that the inorganic binder was not added. The resulting ink had a silver particle concentration of 70%, a solvent concentration of 30%, and a viscosity (at 20° C.) of 80 mPa·s. Electrical Conductor thin films were formed using the resulting ink in the same manner as in Example 1. The firing was conducted at 200° C. or 300° C. each for 1 hour. Separately, the firing was carried out at 300° C. for 0.5 hours, 1 hour, or 5 hours to obtain an electrical conductor thin film. The resulting electrical conductor thin films were evaluated in the same manner as in Example 1. All the electrical conductor thin films were found to have poor adhesion (class 5) and bad surface smoothness, so that they were not evaluated by SEM observation, film thickness measurement, and specific resistance measurement. The results obtained are shown in Table 5 below. The SEM micrographs of the electrical conductor thin films obtained by the firing at 200° C.×1 hour and 300° C.×1 hour are shown in FIG. 5.

TABLE 5

| | | | | | | |
|---|---|---|---|---|---|---|
| Firing Temp. (° C.) | 150 | 200 | 300 | 400 | 500 | 600 |

| | |
|---|---|
| Firing Time (hr) | 1 |

Evaluation:

| Inside | | filmy | filmy | | | |
|---|---|---|---|---|---|---|
| Particle Shape | | | | | | |
| Film | | unmeasurable | unmeasurable | | | |
| Thickness (μm) | | | | | | |
| Specific | | — | — | | | |
| Resistance (Ω · cm) | | | | | | |
| Adhesion (class) | 5 | 5 | 5 | 5 | 5 | 5 |
| Surface Smoothness | bad | bad | bad | bad | bad | bad |
| Firing Temp. (° C.) | 300 | | | | | |
| Firing Time (hr) | 0.5 | 1 | 5 | 10 | 60 | 170 |

Evaluation:

| | | | | | | |
|---|---|---|---|---|---|---|
| Inside | filmy | filmy | filmy | | | |
| Particle Shape | | | | | | |
| Film | unmeasurable | unmeasurable | unmeasurable | | | |
| Thickness (μm) | | | | | | |
| Specific | — | — | — | | | |
| Resistance (Ω · cm) | | | | | | |
| Adhesion (class) | 5 | 5 | 5 | 5 | 5 | 5 |
| Surface Smoothness | bad | bad | bad | bad | bad | bad |

As is apparent from the results shown in Tables 1 through 3 and FIGS. 1 through 3, the electrical conductor thin films formed of the inks of Examples maintained the original nearly spherical shape of the metal particles after firing at 150° C. to 600° C., and the fired film thickness does not change with variation of the firing temperature, proving the high heat/shrinkage resistance of the inks. It is also seen that the electrical conductor thin films show no change of thickness and keep low specific resistance even when fired at 300° C. for a varying firing time up to 170 hours. The results also prove that the electrical conductor thin films of Examples to have high surface smoothness and high adhesion to a glass substrate.

As is apparent from the results of Tables 4 and 5 and FIGS. 4 and 5, in contrast, the electrical conductor thin films formed of the inks of Comparative Examples show a filmy shape of the metal particles as a result of fusion of the particles and have poor adhesion to a glass substrate.

### INDUSTRIAL APPLICABILITY

The present invention provides an electrical conductor thin film with excellent heat/shrinkage resistance and high dimensional stability because the fusion between the fine metal particles during firing can be prevented. The invention provides an electrical conductor thin film with high adhesion to a substrate of various materials.

1. An electrically conductive ink comprising fine metal particles, an inorganic binder, and a solvent, the inorganic binder comprising a coupling agent containing Ti or Al or a chelate containing Ti or Al.

2. The electrically conductive ink according to claim 1, wherein the fine metal particles comprise particles of silver, a silver-platinum alloy or a silver-palladium alloy each having a particle size of 1 to 300 nm.

3. The electrically conductive ink according to claim 1, wherein the inorganic binder comprises at least one of a coupling agent containing Ti or Al and a chelate containing Ti or Al.

4. The electrically conductive ink according to claim 1, further comprising a coupling agent containing Si or Zr or a chelate containing Si or Zr.

5. The electrically conductive ink according to claim 1, wherein the solvent is aqueous or nonaqueous.

6. The electrically conductive ink according to claim 1, wherein the inorganic binder is present in an amount of 1 to 50 parts by weight per 100 parts by weight of the fine metal particles.

7. The electrically conductive ink according to claim 1, which is obtained by adding, to a slurry containing 10% to 80% by weight of the fine metal particles in the solvent, 1 to 50 parts by weight of the inorganic binder per 100 parts by weight of the fine metal particles.

8. The electrically conductive ink according to claim 1, wherein the fine metal particles has a concentration of 10% to 79% by weight, the inorganic binder has a concentration of 0.1% to 29% by weight, and the solvent has a concentration of 14% to 89.9% by weight.

9. A process of producing an electrical conductor thin film comprising printing the electrically conductive ink of claim 1 on a substrate to form a printed pattern by additive processing and firing the printed pattern at 100° C. to 950° C.

10. The process according to claim 9, wherein the printing is inkjet printing.

11. The process according to claim 9, wherein the substrate is made of glass, ceramic or metal.

12. An electrical conductor thin film formed by firing the electrically conductive ink of claim 1, in which film the fine metal particles are each nearly spherical and in electrical contact with each other.

13. The electrical conductor film according to claim 12, having a mirror surface.
